(19) United States
(12) Patent Application Publication
(10) Pub. No.: US 2016/0315280 A1
(43) Pub. Date: Oct. 27, 2016

(54) LIGHT-EMITTING DEVICE AND METHOD FOR FABRICATING LIGHT-EMITTING DEVICE

(71) Applicant: TOPPAN PRINTING CO., LTD., Taito-Ku (JP)

(72) Inventors: Takashi KIZU, Taito-ku (JP); Mikio Baba, Taito-ku (JP)

(73) Assignee: TOPPAN PRINTING CO., LTD., Taito-Ku (JP)

(21) Appl. No.: 15/203,386

(22) Filed: Jul. 6, 2016

Related U.S. Application Data
(63) Continuation of application No. PCT/JP2014/006302, filed on Dec. 17, 2014.

(30) Foreign Application Priority Data
Jan. 16, 2014 (JP) 2014-006013

(51) Int. Cl. H01L 51/52; H01L 51/56

(52) U.S. Cl. CPC H01L 51/5203; H01L 51/56; H01L 51/5237

(57) ABSTRACT

A light-emitting device includes a transparent substrate, a thin line structure formed on a portion of the transparent substrate and including thin lines which are formed in a stripe or lattice pattern, a transparent conductive layer formed on the portion of the transparent substrate where the thin line structure is formed, a light-emitting functional layer formed on a portion of the transparent conductive layer located in a light-emitting region, an electrode positioned on the light-emitting functional layer on an opposite side of the transparent conductive layer in the light-emitting region, and a sealing substrate positioned over the electrode and attached to the transparent substrate via an adhesive. The adhesive is applied to the transparent substrate such that the transparent conductive layer is not interposed between the adhesive and the transparent substrate, and that the adhesive is formed around the light-emitting region in plan view.

### CROSS-REFERENCE TO RELATED APPLICATIONS

The present application is a continuation of International Application No. PCT/JP2014/006302, filed Dec. 17, 2014, which is based upon and claims the benefits of priority to Japanese Application No. 2014-006013, filed Jan. 16, 2014. The entire contents of these applications are incorporated herein by reference.

### BACKGROUND OF THE INVENTION

1. Field of the Invention

The present invention relates to a light-emitting device and a method for fabricating the light-emitting device. The present invention provides a technique relating to a light-emitting device particularly favorable for an organic electroluminescent light-emitting device.

2. Discussion of the Background

In recent years, research and development is underway to provide light-emitting devices having a display panel based on light-emitting elements, as next-generation display devices replacing liquid crystal display devices (LCD). Such a display panel based on light-emitting elements includes two-dimensionally arrayed self-luminous elements, such as organic electroluminescent elements (hereinafter also abbreviated as organic EL elements).

Such an organic EL element includes an anode, a cathode, and an organic EL layer (light-emitting functional layer) formed between this pair of electrodes. The organic EL layer has, for example, an organic light-emitting layer, a hole injection layer, and the like. In the organic EL element, holes and electrons are recombined in the organic EL layer to generate energy, with which light is emitted.

Such an organic EL element has a transparent electrode on a light-extraction side. Typically, the transparent electrode is formed using tin-doped indium oxide (indium tin oxide; ITO), zinc-doped indium oxide (indium zinc oxide; IZO), or the like. In this case, the transparent electrode is required to have a low resistance. To this end, a thick and uniform film must be formed, which, however, causes decrease of light transmittance and increase of cost, and involves high-temperature treatment in the formation process. Therefore, there has been a limitation, in particular, to achieving a low resistance on a film (e.g., see PTL 1).

In this regard, there has been disclosed in recent years a technique for providing a transparent electrode without using ITO. According to the technique, an electrically conductive surface is prepared. The electrically conductive surface is arranged, for example, with a thin line structure such as a uniform mesh, stripe or grid pattern made of metal and/or alloy. The technique proposes a method of forming the transparent electrode. In the method, for example, a transparent conductive layer is formed on the electrically conductive surface by coating or printing an ink which is obtained by dissolving or dispersing an electrically conductive high-molecular-weight material into an appropriate solvent (e.g., see PTLs 2 and 3).
PTL 1: JP-A-H10-162961
PTL 2: JP-A-2005-302508
PTL 3: JP-A-2006-093123

### SUMMARY OF THE INVENTION

According to one aspect of the present invention, a light-emitting device includes a transparent substrate, a thin line structure formed on a portion of the transparent substrate and including thin lines which are formed in a stripe or lattice pattern and include an electrically conductive material, a transparent conductive layer formed on the portion of the transparent substrate where the thin line structure is formed, a light-emitting functional layer formed on a portion of the transparent conductive layer located in a light-emitting region, an electrode positioned on the light-emitting functional layer on an opposite side of the transparent conductive layer in the light-emitting region, and a sealing substrate positioned over the electrode and attached to the transparent substrate via an adhesive. The adhesive is applied to the transparent substrate such that the transparent conductive layer is not interposed between the adhesive and the transparent substrate, and that the adhesive is formed around the light-emitting region in plan view.

According to another aspect of the present invention, a method of manufacturing a light-emitting device includes forming thin lines including an electrically conductive material in a stripe or lattice pattern on a portion of a transparent substrate such that a thin line structure is formed on the portion of the transparent substrate, forming a transparent conductive layer on the portion of the transparent substrate where the thin line structure is formed, forming a light-emitting functional layer on a portion of the transparent conductive layer located in a light-emitting region, positioning an electrode on the light-emitting functional layer on an opposite side of the transparent conductive layer in the light-emitting region, applying an adhesive to the transparent substrate, and attaching a sealing substrate to the transparent substrate via the adhesive such that the sealing substrate is positioned over the electrode. The adhesive is applied to the transparent substrate such that the transparent conductive layer is not interposed between the adhesive and the transparent substrate, and that the adhesive is formed around the light-emitting region in plan view.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic plan view illustrating a configuration of a transparent electrode according to a first embodiment.

FIGS. 2(a) and 2(b) are a set of schematic cross-sectional views illustrating a principal part of an organic electroluminescent element including the transparent electrode according to the first embodiment, with FIG. 2(a) being taken along the line A-A of FIG. 1, with FIG. 2(b) being taken along the line B-B of FIG. 1.

FIG. 3 is a schematic plan view illustrating another configuration of the transparent electrode according to the first embodiment.

FIG. 4 is a schematic plan view illustrating still another configuration of the transparent electrode according to the first embodiment.

FIG. 5 is a schematic plan view illustrating a configuration of a transparent electrode according to a second embodiment.

FIG. 6 is a schematic plan view illustrating another configuration of the transparent electrode according to the second embodiment.

### DESCRIPTION OF THE EMBODIMENTS

The embodiments will now be described with reference to the accompanying drawings, wherein like reference numerals designate corresponding or identical elements throughout the various drawings.

Hereinafter will be described a method for fabricating a light-emitting device, and the light-emitting device itself, according to some embodiments of the present invention.

The following description is provided by way of an example of an organic EL light-emitting device, as the light-emitting device, that uses an organic EL element. It should be noted that light-emitting functions should not be construed as being limited to those of an organic EL element.

The organic EL light-emitting device of each of the following embodiments has a structure in which an organic EL element is formed on a transparent substrate, and a light-emitting region of the organic EL element is sealed by a transparent substrate, an adhesive, and a sealing substrate. A transparent electrode includes a thin line structure and a transparent conductive layer. As described later, the following embodiments each adopt a structure in which the transparent conductive layer is not interposed between the adhesive and the transparent substrate.

### First Embodiment

The following description sets forth a configuration of a transparent electrode and a method for fabricating the transparent electrode, according to a first embodiment.

<Configuration of Transparent Electrode>

The transparent electrode of the present embodiment includes a thin line structure made of metal and/or alloy, and a transparent conductive layer formed by coating or printing. The transparent electrode is provided on a transparent substrate, with the thin line structure and the transparent conductive layer being laminated in this order from the transparent substrate side, for example.

From the viewpoint of improving luminance when used for an organic EL element, the transparent electrode of the present embodiment preferably has a surface resistivity, in a conductive surface thereof, in the range of 0.01 Ω/sq. to 100 Ω/sq., inclusive, and more preferably in the range of 0.1 Ω/sq. to 10 Ω/sq., inclusive.

The transparent electrode of the present embodiment can be used for: transparent electrodes such as of LCDs, electroluminescent elements, plasma displays, electrochromic displays, solar batteries, or touch panels; electronic paper; electromagnetic wave shielding materials; and the like. The transparent electrode of the present embodiment, in particular, has good electrical conductivity and transparency, and also has good smoothness, and hence is preferably used for organic EL elements.

(Transparent Substrate)

In the transparent electrode of the present embodiment, a plastic film, a plastic plate, glass, or the like can be used as a transparent substrate.

Materials that can be used for the plastic film and the plastic plate include, for example: polyesters, such as polyethylene terephthalate (PET) or polyethylene naphthalate; polyolefins, such as polyethylene (PE), polypropylene (PP), polystyrene or EVA; vinyl resins, such as polyvinyl chloride or polyvinylidene chloride; polyether ether ketone (PEEK); polysulfone (PSF); polyether sulfone (PES); polycarbonate (PC); polyamide; polyimide; acrylic resins; triacetyl cellulose (TAC); or the like.

As the transparent substrate, one having good surface smoothness is preferable. The surface smoothness of the transparent substrate preferably has an arithmetic average roughness Ra of 5 nm or less and a maximum height Ry of 50 nm or less, and more preferably has Ra of 1 nm or less and Ry of 20 nm or less. The surface of the transparent substrate may be smoothed by providing thereto a primer coat layer made of a thermosetting resin, an ultraviolet curable resin, an electron beam curable resin, a radiation curable resin, or the like, or can also be smoothed by machining, such as polishing. To improve coatability and adhesiveness of the transparent conductive layer, the transparent substrate may be surface-treated using corona, plasma, or UV/ozone. The surface smoothness can be calculated from a measurement performed by an atomic force microscope (AFM) or the like.

The transparent electrode of the present embodiment is preferably provided with a gas barrier layer for the purpose of shielding against oxygen and moisture in the air. As materials used for forming the gas barrier layer, mention can be made of silicon oxide, silicon nitride, silicon oxynitride, and metal oxides and metal nitrides such as aluminum nitride and aluminum oxide. These materials also serve as an oxygen barrier, in addition to a water vapor barrier. In particular, the material for forming the gas barrier layer is preferably silicon nitride or a silicon oxynitride having good barrier properties, solvent resistance, and transparency. The gas barrier layer can have a multilayer configuration as needed. In this case, the gas barrier layer may be made up of only inorganic layers, or may be made up of inorganic and organic layers. As a method of forming the gas barrier layer, resistance heating vapor deposition, electron beam vapor deposition, reactive vapor deposition, ion plating, or sputtering can be used, depending on materials. There is no particular limitation in the thickness of the gas barrier layer, but typically, the thickness of the gas barrier layer preferably falls within the range of 5 nm to 500 nm per layer, and more preferably within the range of 10 nm to 200 nm per layer. The gas barrier layer is provided on at least one surface of the transparent substrate. The gas barrier layer is preferably provided on both surfaces of the transparent substrate.

(Thin Line Structure)

As the thin line structure of the present embodiment, one having low electrical resistance is preferable, and materials having electrical conductivity of 10⁷ S/cm or more are typically used therefor. Specific examples of such conductive materials include metals, such as aluminum, silver, chromium, gold, copper, tantalum and molybdenum, and/or alloys thereof. Of these materials, taking account of high electrical conductivity and ease of material handling, aluminum, chromium, copper, silver, and alloys thereof are preferable.

In the present embodiment, a plurality of thin lines made of the above-mentioned conductive materials are arranged on a surface of the transparent substrate in a uniform mesh, stripe or grid pattern, for example, to configure the thin line structure. Thus, in the present embodiment, an electrically conductive surface is prepared by arranging a plurality of thin lines to improve electrical conductivity of the transparent electrode. The width of each of the thin lines made of metal or alloy is not particularly specified, but a width falling within the range of 0.1 μm to 1000 μm is preferable. Adjacent thin lines are preferably arranged with a pitch of or at intervals of 50 μm to 5 cm, but a pitch in the range of 100 μm to 1 cm, inclusive, is particularly preferable.

The transparent substrate suffers decrease in light transmittance due to arrangement of the thin line structure thereon. It is important that the decrease is as small as possible. Accordingly, it is important not to adopt an excessively small interval between the thin lines or not to impart an excessively large width to the thin lines. Preferably, it is important to set the interval and the width of the thin lines such that light transmittance of 80% or more is ensured. The thin line width may be determined according to purposes. However, when the relationship between the thin line width and the thin line interval is concerned in terms of the layout in plan view, the thin line width is preferably in the range of 1/10000 to ⅕, inclusive, and more preferably in the range of 1/100 to 1/10, inclusive, of the thin line interval.

The height (thickness) of the thin line structure is preferably in the range of 0.05 μm to 10 μm, inclusive, and more preferably in the range of 0.1 μm to 1 μm, inclusive. The thin line height may be determined according to desired electrical conductivity. However, when a relationship between the thin line width and the thin line height is concerned, the thin line height is preferably in the range of 1/10000 to ten fold, inclusive, of the thin line width. The thin line structure can be formed into a multilayer configuration as needed. In this case, the thin line structure may be formed of a single conductive material, or may be formed of several conductive materials.

(Transparent Conductive Layer)

A solution used when forming the transparent conductive layer by coating contains a solvent and a material that serves as the transparent conductive layer. The transparent conductive layer preferably contains a high-molecular-weight compound exhibiting electrical conductivity. The high-molecular-weight compound may contain a dopant. The electrical conductivity of the high-molecular-weight compound in terms of specific conductance is typically in the range of 10⁻⁵ S/cm to 10⁵ S/cm, and preferably in the range of 10⁻³ S/cm to 10⁵ S/cm. Preferably, the transparent conductive layer consists of a high-molecular-weight compound exhibiting electrical conductivity. As materials for forming the transparent conductive layer, mention can be made of polyaniline and its derivatives, polythiophene and its derivatives, and the like. As the dopant, a known dopant can be used. Examples of dopants that can be used include: organic sulfonic acids, such as polystyrene sulfonic acid and dodecylbenzenesulfonic acid; and a Lewis acids, such as PF₅, AsF₅, or SbF₅. The high-molecular-weight compound exhibiting electrical conductivity may be of self-doped type in which a dopant is directly bonded to a high-molecular-weight compound.

The transparent conductive layer is preferably formed containing a polythiophene and/or a derivative thereof, but preferably formed consisting of a polythiophene and/or a derivative thereof. The polythiophene and/or the derivative thereof may contain a dopant. A polythiophene, a derivative thereof, or a mixture of the polythiophene and the derivative thereof is easily dissolved or dispersed in an aqueous solvent, such as water or alcohol, and thus is favorably used as a solute of a coating liquid used for coating. These materials have high electrical conductivity and accordingly are favorably used as electrode materials. Further, these materials have HOMO energy of approximately 5.0 eV which is different, by only 1 eV or so, from the HOMO energy of an organic light-emitting layer used for a typical organic EL element. Accordingly, use of these materials enables efficient injection of holes into the organic light-emitting layer. Therefore, in particular, these materials are favorably used as anode materials. Also, these materials exhibit high transparency and accordingly are favorably used for emitted-light-extraction side electrodes of organic EL elements.

The transparent conductive layer is preferably formed containing polyaniline and/or a derivative thereof, but preferably formed consisting of polyaniline and/or a derivative thereof. Polyaniline and/or derivatives thereof may contain a dopant. Polyaniline and/or derivatives thereof, which have good electrical conductivity and stability, are favorably used as electrode materials. These materials have high transparency and accordingly are favorably used for emitted-light-extraction side electrodes of organic EL elements.

<Method for Fabricating Transparent Electrode>

A method for fabricating a transparent electrode according to the present embodiment will be described.

In the present embodiment, a transparent electrode is provided on a transparent substrate, and the transparent electrode is prepared by forming a thin line structure and a transparent conductive layer, in this order, on the transparent substrate.

In plan view, a region on the transparent substrate has a light-emitting region 14 in a center portion, an adhesive-forming region 16 surrounding the light-emitting region 14, and an outer peripheral region outside the adhesive-forming region 16 (see FIG. 1).

In the method for fabricating a transparent electrode according to the present embodiment, a thin line structure described above is formed first on one surface of the transparent substrate described above. The thin line structure is formed in the light-emitting region, with a part thereof being extended to the outer peripheral region.

There is no particular limitation in a method of forming the thin line structure. For example, in a method, a film made of a thin-line-structure material is formed by using resistance heating vapor deposition, electron beam vapor deposition, sputtering, lamination in which a thin metal film is thermally compressed, or the like, followed by forming the above-mentioned pattern by etching using a photoresist.

As an example of film formation, a solution containing a thin-line-structure material can be used. There is no particular limitation in a solvent used for the film formation, as long as the material for forming the thin line structure can be dissolved in the solvent. Solution-based film formation methods can include coating methods, such as spin coating, casting, micro gravure coating, gravure coating, bar coating, roll coating, wire bar coating, dip coating, spray coating, screen printing, flexographic printing, offset printing, slit coating, ink jet printing, and nozzle printing. It is particularly preferable that, in a film formation using a solution, the above-mentioned pattern is directly formed. The method of film formation can be selected as appropriate, but it is preferable to use printing, such as screen printing, flexographic printing, or offset printing, or to use coating based on injection such as of ink jet printing or nozzle printing. Afterwards, the solution is dried and solidified to form the thin line structure.

Next, in the fabrication method of the present embodiment, a conductive coating material is applied to a region on the transparent substrate, where a transparent electrode is to be formed and where the thin line structure has been formed, to thereby form the transparent conductive layer on the transparent substrate. In this case, the transparent conductive layer is formed except in the adhesive-forming region which is for forming an adhesive of the sealing substrate (details will be described later) which is bonded to the transparent substrate. Film formation methods can include coating methods, such as spin coating, casting, micro gravure coating, gravure coating, bar coating, roll coating, wire bar coating, dip coating, spray coating, screen printing, flexographic printing, offset printing, slit coating, ink jet printing, and nozzle printing. In particular, since the film is formed throughout the surface of the region where a transparent electrode is to be formed, a method enabling uniform coating of a film is preferable. From this viewpoint, preferable film formation methods are coating methods, such as spin coating, bar coating, wire bar coating, dip coating, spray coating, slit coating, casting, micro gravure coating, gravure coating, and roll coating.

Next, in the fabrication method of the present embodiment, the transparent substrate, to which the conductive coating material serving as a transparent electrode has been applied, is heat-treated at 100° C. or more, for example, in a dry treatment chamber. Thus, the solvent contained in the solution of the conductive coating material is vaporized to solidify the conductive coating material, for adhesion onto the transparent substrate where the thin line structure has been formed, thereby forming the transparent conductive layer.

<Configuration of Organic EL Element>

The organic EL element of the present embodiment includes a transparent electrode having the configuration described above. The organic EL element of the present embodiment uses the transparent electrode as an anode. Any material or structure generally used for organic EL elements can be used for the organic light-emitting layer, the cathode and the sealing structure. For example, the electrode and the light-emitting functional layer of the organic EL element can have layered configurations as exemplified below.

Anode/organic light-emitting layer/cathode,

Anode/hole transport layer/organic light-emitting layer/electron transport layer/cathode,

Anode/hole injection layer/hole transport layer/organic light-emitting layer/electron transport layer/cathode,

Anode/hole injection layer/organic light-emitting layer/an electron transport layer/electron injection layer/cathode,

Anode/hole injection layer/organic light-emitting layer/electron injection layer/cathode,

where, the symbol “/” indicates that the layers mentioned before and after the symbol “/” are adjacently laminated. The same applies to the following description.

The organic EL element of the present embodiment may have two or more organic light-emitting layers (light-emitting functional layers). An organic EL element with two organic light-emitting layers can have the following layered configuration.

Anode/charge injection layer/hole transport layer/organic light-emitting layer/electron transport layer/charge injection layer/charge generation layer/charge injection layer/hole transport layer/organic light-emitting layer/electron transport layer/charge injection layer/cathode.

An organic EL element with three or more organic light-emitting layers can have the following layered configuration including two or more repetition units, one repetition unit specifically being: charge generation layer/charge injection layer/hole transport layer/organic light-emitting layer/electron transport layer/charge injection layer.

Anode/charge injection layer/hole transport layer/organic light-emitting layer/electron transport layer/charge injection layer/(repetition unit)/(repetition unit)/ . . . /cathode.

In the layered configurations set forth above, layers other than the anode, the cathode, and the organic light-emitting layer can be omitted as necessary.

The charge generation layer refers to a layer that generates holes and electrons when electric field is applied thereto. Examples of the charge generation layer can include thin films such as of vanadium oxide, ITO, molybdenum oxide, or the like.

The following description addresses the hole injection layer, the hole transport layer, the organic light-emitting layer, the electron transport layer, the electron injection layer, and the cathode, as well as the sealing structure.

(Layer Provided Between Anode and Organic Light-Emitting Layer)

Layers provided, as necessary, between the anode and the organic light-emitting layer include a hole injection layer, a hole transport layer, an electron blocking layer, and the like. The hole injection layer serves as a layer for improving efficiency of hole injection from the anode, and the hole transport layer serves as a layer for improving hole injection from the hole injection layer or from a layer closer to the anode. If the hole injection layer or the hole transport layer serves as a layer blocking transport of electrons, the layer may be referred to as an electron blocking layer. Whether the layer has the function or effect of blocking transport of electrons can be confirmed, for example, by preparing an element that allows passage of only electron current therethrough and by detecting a decrease in the current value.

(Hole Injection Layer)

The hole injection layer can be provided between the anode and the hole transport layer, or between the anode and the organic light-emitting layer. As materials forming the hole injection layer, known materials can be used as appropriate, with no particular limitation. Examples of such materials include phenylamine-based materials, starburst amine-based materials, phthalocyanine materials, hydrazone derivatives, carbazole derivatives, triazole derivatives, imidazole derivatives, oxadiazole derivatives having an amino group, oxides such as vanadium oxide, tantalum oxide or molybdenum oxide, amorphous carbon, polyaniline, polythiophene derivatives, and the like.

Film formation methods for the hole injection layer can include film formation using a solution that contains a material serving as the hole injection layer (hole injection material). There is no particular limitation in the solvent used for the solution-based film formation, as long as the hole injection material can be dissolved in the solvent. As such solvents, mention can be made of chlorine solvents such as chloroform, methylene chloride and dichloroethane, ether solvents such as tetrahydrofuran, aromatic hydrocarbon solvents such as toluene and xylene, ketone solvents such as acetone or methyl ethyl ketone, ester solvents such as ethyl acetate, butyl acetate and ethyl cellosolve acetate, and water.

Solution-based film formation methods include coating methods, such as spin coating, casting, micro gravure coating, gravure coating, bar coating, roll coating, wire bar coating, dip coating, spray coating, screen printing, flexographic printing, offset printing, slit coating, ink jet printing, and nozzle printing.

The hole injection layer preferably has a thickness approximately in the range of 5 to 300 nm. If the thickness is less than 5 nm, preparation of the hole injection layer tends to be difficult. On the other hand, if the thickness exceeds 300 nm, the drive voltage and the voltage applied to the hole injection layer tend to be increased.

(Hole Transport Layer)

There is no particular limitation in materials forming the hole transport layer. Materials for the hole transport layer can include aromatic amine derivatives, such as N,N′-diphenyl-N,N′-di(3-methylphenyl)4,4′-diaminobiphenyl (TPD) and 4,4′-bis[N-(1-naphthyl)-N-phenylamino]biphenyl(NPB), polyvinyl carbazole or derivatives thereof, polysilane or derivatives thereof, polysiloxane derivatives having aromatic amine in a side chain or the main chain, pyrazoline derivatives, arylamine derivatives, stilbene derivatives, triphenyldiamine derivatives, polyaniline or derivatives thereof, polythiophene or derivatives thereof, polyallylamine or derivatives thereof, polypyrrole or derivatives thereof, poly(p-phenylene vinylene) or derivatives thereof, and poly(2,5-thienylene vinylene) or derivatives thereof.

Of these materials for the hole transport layer, preferably used materials are high-molecular-weight hole transport materials, such as polyvinyl carbazole or derivatives thereof, polysilane or derivatives thereof, polysiloxane derivatives having an aromatic amine in a side chain or the main chain, polyaniline or derivatives thereof, polythiophene or derivatives thereof, polyallylamine or derivatives thereof, poly(p-phenylene vinylene) or derivatives thereof, or poly(2,5-thienylene vinylene) or derivatives thereof. When a low-molecular-weight hole transport material is used, the hole transport material is preferably dispersed in a high-molecular-weight binder.

There is no particular limitation in the method of forming the hole transport layer. When using a low-molecular-weight hole transport material, the film of the hole transport layer can be formed from a mixed solution containing a high-molecular-weight binder and a hole transport material. When using a high-molecular-weight hole transport material, the film of the hole transport layer can be formed from a solution containing a hole transport material. There is no particular limitation in the solvent used for the solution-based film formation, as long as the hole transport material can be dissolved in the solvent. Examples of such solvents include those which have been exemplified in the hole injection layer section described above. Solution-based film formation methods can include coating methods similar to those used for the hole injection layer mentioned above.

The thickness of the hole transport layer is not particularly limited, but can be changed as appropriate according to desired designs. The thickness is preferably in the range of about 1 to 1000 nm. If the thickness is less than the lower limit, preparation of the hole transport layer tends to be difficult, and there is also a tendency, for example, of not being able to obtain a sufficient hole transport effect. On the other hand, if the thickness exceeds the upper limit, the drive voltage and the voltage applied to the hole transport layer tend to be increased. Therefore, the thickness of the hole transport layer is preferably in the range of 1 to 1000 nm, more preferably in the range of 2 to 500 nm, and still more preferably in the range of 5 to 200 nm.

(Organic Light-Emitting Layer)

The organic light-emitting layer has an organic substance (low- and high-molecular-weight compounds) mainly emitting fluorescent light or phosphorescent light. The organic light-emitting layer may further contain a dopant material. Materials that can be used for forming the organic light-emitting layer of the present embodiment include the following materials, for example:

“Dye Material”

As dye materials, mention can be made, for example, of cyclopentamine derivatives, quinacridone derivatives, coumarin derivatives, tetraphenylbutadiene derivative compounds, triphenylamine derivatives, oxadiazole derivatives, pyrazoloquinoline derivatives, distyrylbenzene derivatives, distyrylarylene derivatives, pyrrole derivatives, thiophene ring compounds, pyridine ring compounds, perinone derivatives, perylene derivatives, oligothiophene derivatives, oxadiazole dimers, pyrazoline dimers, and the like.

“Metal Complex Material”

As metal complex materials, mention can be made, for example, of: metal complexes capable of emitting light from a triplet excitation state, such as iridium complexes or platinum complexes; and metal complexes having, as a center metal, Al, Zn, Be or the like, or a rare earth metal such as Tb, Eu, Dy or the like, and having, as a ligand, an oxadiazole, thiadiazole, phenylpyridine, phenylbenzimidazole or quinoline structure, or the like, such as an aluminum quinolinol complex, benzoquinolinol beryllium complex, benzoxazolyl zinc complex, benzothiazole zinc complex, azomethyl zinc complex, porphyrin zinc complex, europium complex, and the like

“High-Molecular-Weight Material”

As high-molecular-weight materials, mention can be made of polyparaphenylene vinylene derivatives, polythiophene derivatives, polyparaphenylene derivatives, polysilane derivatives, polyacetylene derivatives, polyfluorene derivatives, polyvinyl carbazole derivatives, materials obtained by polymerizing the foregoing dye materials or metal complex light-emitting materials, and the like.

Of the light-emitting materials set forth above, blue light-emitting materials include distyrylarylene derivatives, oxadiazole derivatives, polymers of these materials, polyvinyl carbazole derivatives, polyparaphenylene derivatives, polyfluorene derivatives, and the like.

Green light-emitting materials include quinacridone derivatives, coumarin derivatives, polymers of these materials, polyparaphenylene vinylene derivatives, polyfluorene derivatives, and the like.

Red light-emitting materials include coumarin derivatives, thiophene ring compounds, polymers of these materials, polyparaphenylene vinylene derivatives, polythiophene derivatives, polyfluorene derivatives, and the like.

“Dopant Material”

A dopant can be added to the organic light-emitting layer for the purpose of improving light-emitting efficiency or changing a wavelength of emitted light. Such dopants can include, for example, perylene derivatives, coumarin derivatives, rubrene derivatives, quinacridone derivatives, squarylium derivatives, porphyrin derivatives, styryl dyes, tetracene derivatives, pyrazolone derivatives, decacyclene, phenoxazone, and the like. The organic light-emitting layer typically has a thickness in the range of about 2 to 200 nm.

Methods of forming the organic light-emitting layer can include film formation from a solution that contains an organic light-emitting material. Any solvent can be used for the solution-based film formation, as long as the organic light-emitting material can be dissolved in the solvent. As examples, the solvents exemplified in the hole injection layer section can be used. As solution-based film formation methods, coating methods similar to those for forming the foregoing hole injection layer can be used.

(Layer Provided Between Cathode and Light-Emitting Layer)

Layers provided, as necessary, between the cathode and the organic light-emitting layer can be an electron injection layer, an electron transport layer, a hole blocking layer, and the like. If both of the electron injection layer and the electron transport layer are provided between the cathode and the organic light-emitting layer, the layer in contact with the cathode is referred to as an electron injection layer, and layers except for the electron injection layer are referred to as electron transport layers.

The electron injection layer serves as a layer improving efficiency of electron injection from the cathode. The electron transport layers each serves as a layer improving efficiency of electron injection from the cathode, the electron injection layer, or a layer closer to the cathode. The hole blocking layer serves as a layer blocking transport of holes. If the electron injection layer and/or the electron transport layers serves as layer(s) blocking transport of holes, these layers may also serve as hole blocking layers.

(Electron Transport Layer)

As electron transport materials forming the electron transport layer, known materials can be used. Electron transport materials can include oxadiazole derivatives, anthraquinodimethane or derivatives thereof, benzoquinone or derivatives thereof, naphthoquinone or derivatives thereof, anthraquinone or derivatives thereof, tetracyano anthraquinodimethane or derivatives thereof, fluorenone or derivatives thereof, diphenyl dicyanoethylene or derivatives thereof, diphenoquinone derivatives, 8-hydroxyquinoline or metal complexes of 8-hydroxyquinoline derivatives, polyquinoline or derivatives thereof, polyquinoxaline or derivatives thereof, polyfluorene or derivatives thereof, and the like.

Of these electron transport materials, preferably used materials are oxadiazole derivatives, benzoquinone or derivatives thereof, anthraquinone or derivatives thereof, 8-hydroxyquinoline or metal complexes of 8-hydroxyquinoline derivatives, polyquinoline or derivatives thereof, polyquinoxaline or derivatives thereof, and polyfluorene or derivatives thereof, and more preferably used materials are 2-(4-biphenyl)-5-(4-t-butylphenyl)-1,3,4-oxadiazole, benzoquinone, anthraquinone, tris(8-quinolinol)aluminum, and polyquinoline.

There is no particular limitation in the method of forming the electron transport layer. When using a low-molecular-weight hole transport material, the film of the hole transport layer can be formed from a mixed solution containing a high-molecular-weight binder and a hole transport material. When using a high-molecular-weight hole transport material, the film of the hole transport layer can be formed from a solution containing a hole transport material. There is no particular limitation in the solvent used for the solution-based film formation, as long as the hole transport material can be dissolved in the solvent. Examples of such solvents include those which have been exemplified in the hole injection layer section described above. Solution-based film formation methods can include coating methods similar to those used for the hole injection layer mentioned above.

The thickness of the electron transport layer has an optimum value which depends on a material to be used. The thickness can be changed as appropriate according to desired designs, but at least a thickness causing no pinholes is required. For example, the film thickness is preferably in the range of approximately 1 to 1000 nm, more preferably in the range of 2 to 500 nm, and still more preferably in the range of 5 to 200 nm.

(Electron Injection Layer)

An optimum material for forming the electron injection layer is selected as appropriate according to the type of the organic light-emitting layer. Materials for the electron injection layer can include alkali metals, alkaline-earth metals, alloys containing one or more of alkali metals and alkaline-earth metals, oxides, halides or carbonates of alkali metals or alkaline-earth metals, or mixtures of these substances. Examples of alkali metals, and oxides, halides and carbonates of alkali metals can include lithium, sodium, potassium, rubidium, cesium, lithium oxide, lithium fluoride, sodium oxide, sodium fluoride, potassium oxide, potassium fluoride, rubidium oxide, rubidium fluoride, cesium oxide, cesium fluoride, lithium carbonate, and the like. Examples of alkaline-earth metals, and oxides, halides and carbonates of alkaline-earth metals can include magnesium, calcium, barium, strontium, magnesium oxide, magnesium fluoride, calcium oxide, calcium fluoride, barium oxide, barium fluoride, strontium oxide, strontium fluoride, magnesium carbonate, and the like. The electron injection layer may be made up of a laminate in which two or more layers are laminated. For example, the laminate may be made up of lithium fluoride/calcium, and the like. The electron injection layer is formed through various vapor deposition methods, sputtering, various coating methods, or the like. The electron injection layer preferably has a thickness in the range of approximately 1 to 1000 nm.

(Cathode)

Materials used for the cathode preferably have a small work function and enable easy electron injection into the organic light-emitting layer, and/or have high electrical conductivity, and/or have high visible light reflectance. Such cathode materials specifically include metals, metal oxides, alloys, graphite or graphite intercalation compounds, inorganic semiconductors such as of zinc oxide, or the like.

As the above metals, alkali metals, alkaline-earth metals, transition metals, III-b group metals, or the like can be used. Specific examples of these metals can include lithium, sodium, potassium, rubidium, cesium, beryllium, magnesium, calcium, strontium, barium, gold, silver, platinum, copper, manganese, titanium, cobalt, nickel, tungsten, tin, aluminum, scandium, vanadium, zinc, yttrium, indium, cerium, samarium, europium, terbium, ytterbium, and the like.

The alloys can include alloys containing at least one of the metals set forth above. Specifically, such alloys can include magnesium-silver alloys, magnesium-indium alloys, magnesium-aluminum alloys, indium-silver alloys, lithium-aluminum alloys, lithium-magnesium alloys, lithium-indium alloys, calcium-aluminum alloys, and the like.

The cathode is formed as a transparent electrode as needed. Materials for the cathode as a transparent electrode can include conductive oxides, such as indium oxide, zinc oxide, tin oxide, ITO and IZO, and conductive organic substances, such as polyaniline or derivatives thereof, and polythiophene or derivatives thereof.

The cathode may be formed as a lamination structure having two or more layers. The electron injection layer may be used as the cathode.

The thickness of the cathode can be selected as appropriate taking account of electrical conductivity or durability. For example, the thickness is in the range of 10 to 10000 nm, preferably in the range of 20 to 1000 nm, and still more preferably in the range of 50 to 500 nm.

(Sealing Structure)

In the present embodiment, an adhesive is used to form an adhesion layer on a sealing substrate, followed by bonding, thereby sealing the light-emitting region. The adhesion layer may be formed first on a transparent substrate 11 side. A thermosetting adhesion layer can also be used as the adhesion layer. However, in view of the influence on the material forming the organic EL element, a photocurable adhesive is preferable. Materials used for the adhesive include, for example, various acrylates, such as ester acrylate, urethane acrylate, epoxy acrylate, melamine acrylate and acrylic resin acrylate, radical-based adhesives using resins such as urethane polyester, cation-based adhesives using resins such as epoxy and vinyl ether, thiol-ene-added-resin-based adhesives, and the like. Of the above adhesives, cation-based adhesives are preferable because cation-based adhesives are free from oxygen inhibition and maintain the progress of polymerization reactions after light irradiation. As cation-based curable adhesives, ultraviolet curable epoxy resin adhesives are preferable. However, particularly preferable ultraviolet curable adhesives are those which are cured within 10 to 90 seconds when irradiated with ultraviolet light of 100 mW/cm² or more. Such adhesives can be sufficiently cured within this time period to achieve appropriate adhesion strength, while eliminating the influence of the ultraviolet irradiation on other components. From the viewpoint of efficiency of production as well, curing within the above time period is preferable. Regardless of the types of adhesives, it is preferable that adhesives have low moisture permeability and high adhesiveness. Examples of the method of forming the adhesion layer on the sealing substrate can include dispensing, extrusion lamination, melting/hot-melting, calendering, nozzle coating, screen printing, vacuum lamination, heat roll lamination, or the like. There is no particular limitation in the thickness of the adhesion layer, but, preferably, the adhesion layer has a small thickness in the range of 1 to 100 μm, and particularly preferably in the range of 5 to 50 μm.

In the case of a top emission-type organic EL element requiring transparency, the sealing substrate can be formed of glass or can be a plastic film such as of polyethylene terephthalate (PET), polyethersulfone (PES) or polyethylene naphthalate (PEN). In the case of a bottom emission-type organic EL element not particularly requiring transparency, the sealing substrate can be formed of a metal material such as stainless steel or aluminum, opaque glass, or a plastic material, in addition to the foregoing materials.

The organic EL light-emitting device is configured as has been described so far.

The organic EL light-emitting device of the present embodiment can be used for self-luminous displays, backlights for liquid crystal, lighting fixtures, and the like.

### Advantageous Effects and Others

Referring now to FIGS. 1-4, hereinafter will be described advantageous effects obtained when using the foregoing configuration of the transparent electrode and its fabrication method.

FIG. 1 is a schematic plan view illustrating a thin line structure 12 and a transparent conductive layer 13, which are formed on a transparent substrate 11. For the sake of clarity, FIG. 1 only shows regions for forming a sealing substrate-arranging region 15, an adhesive-forming region 16 and a light-emitting region 14, and omits an organic EL layer 21, a cathode layer 22 and a sealing substrate 23. In the example shown in FIG. 1, the thin line structure 12 is arranged in a grid pattern on the transparent substrate 11, but there is no particular limitation.

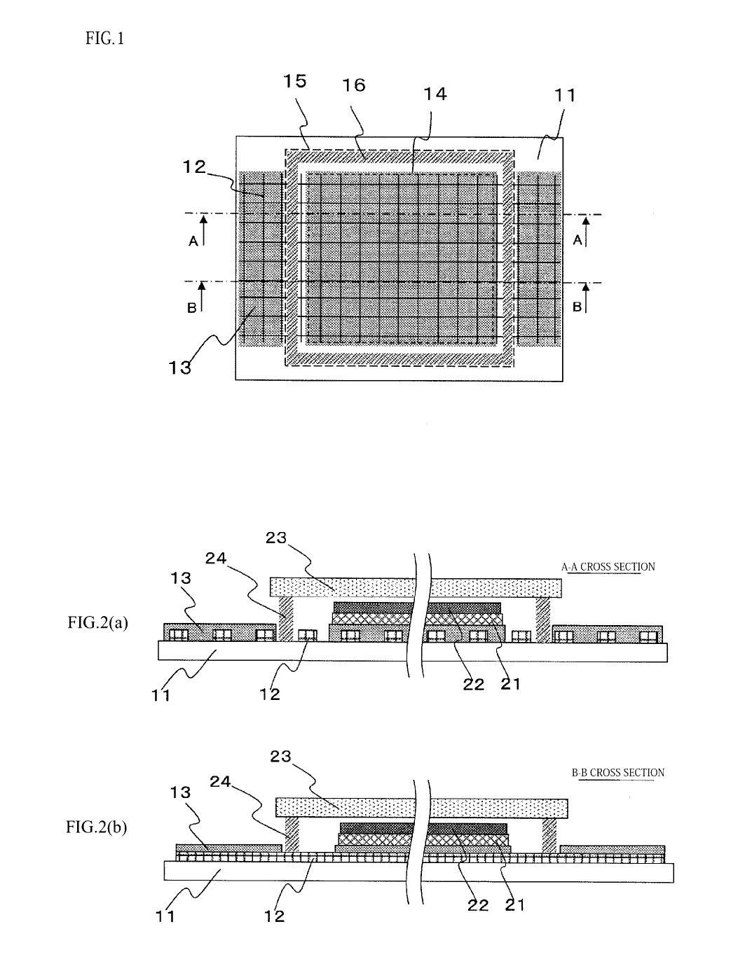

FIGS. 2(a) and 2(b) are a set of schematic cross-sectional views each illustrating an organic EL element prepared using the transparent electrode of the present embodiment. For the sake of clarity, a term “organic EL layer 21” is used herein. However, any configuration may be used as long as the configuration corresponds to the layered configurations of the foregoing organic EL element.

As shown in FIG. 1, in the transparent electrode of the present embodiment, the thin line structure 12 is formed at least in the light-emitting region on the transparent substrate 11. The thin line structure 12 is formed such that a part thereof extends outside the sealing substrate-arranging region 15. By forming the thin line structure 12 being extended outside the sealing substrate-arranging region 15, the thin line structure 12 can also serve as an extraction electrode outside the sealing substrate.

After that, in the present embodiment, the transparent conductive layer 13 is formed in a region except for the adhesive-forming region 16 to thereby prepare the transparent electrode. In this case, the transparent conductive layer 13 is also formed in a region where the thin line structure 12 is formed being extending outside the adhesive-forming region 16. Thus, the extraction electrode outside the sealing substrate 23 can be prepared as a uniform surface electrode. Therefore, no high alignment precision is involved in a subsequent step of connecting the electrodes to a drive circuit, and thus there is an effect of simplifying processing steps.

Further, in the transparent electrode of the present embodiment, an adhesive 24 is arranged on the adhesive-forming region 16 surrounding the light-emitting region 14, while the transparent substrate 11 and the sealing substrate 23 are bonded via the adhesive 24 to join these components 11 and 23.

When an organic EL element is prepared using the transparent electrode of the present embodiment, part of the adhesive 24 is in intimate contact with the thin line structure 12 as shown in FIG. 2 (b), but the rest of the adhesive 24 is in intimate contact with the transparent substrate 11 as shown in FIG. 2 (a). Thus, in the transparent electrode of the present embodiment, there is no region where the transparent conductive layer 13 is in intimate contact with the adhesive 24. In other words, the adhesive 24 is joined to the transparent substrate 11 without allowing the transparent conductive layer 13 to interpose therebetween. Therefore, there can be obtained an organic EL element which has high adhesiveness and is resistant to peeling. In the transparent electrode of the present embodiment, entry of moisture or the like via the transparent conductive layer 13 can be prevented, and therefore an organic EL element ensuring high reliability for a long time can be obtained.

As comparison, an organic EL element was prepared using a transparent electrode in which the thin line structure 12 was entirely covered with the transparent conductive layer 13. In the comparative example, most part of the adhesive 24 was in intimate contact with the transparent conductive layer 13, resulting in lower adhesiveness than that between the sealing substrate 23 and the adhesive 24 and thus causing peeling at an interface between the transparent conductive layer 13 and the adhesive 24. The comparative example was poor in reliability, and there were observed luminance reduction and non-light-emitting region formation after long-term storage.

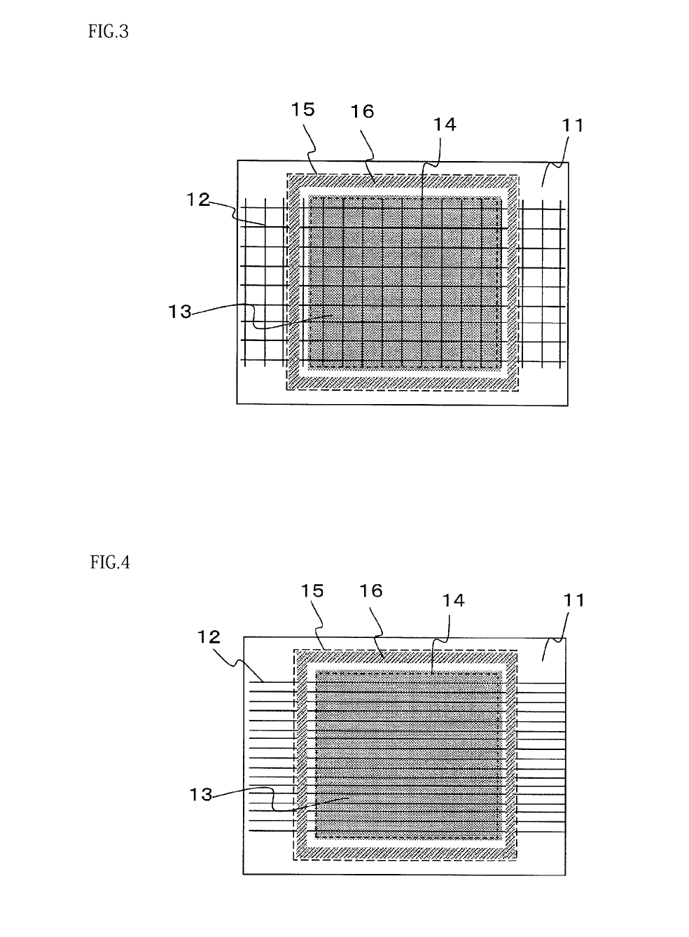

In the configuration described above, the transparent conductive layer 13 was also formed outside the adhesive-forming region 16, while formation in the adhesive-forming region 16 was minimized. In contrast to this, as shown in FIG. 3, the transparent conductive layer 13 may further be limited in its formation range, and thus may be formed only in a range inside the adhesive-forming region 16. In this case as well, there is no region where the transparent conductive layer 13 is in intimate contact with the adhesive 24, similar to the case described above, and hence similar advantageous effects can be obtained.

Let us discuss the case where the thin line structure 12 is formed in a grid pattern and where the thin line structure 12 is defined, on a direction basis, by a row direction (right-and-left direction as viewed in FIGS. 1 and 3) and by a column direction (up-and-down direction as viewed in FIGS. 1 and 3). In this case, only the thin line structure 12 extending in the row direction perpendicular to the adhesive 24 is formed below the adhesive 24. Therefore, in this case, there is no thin line structure 12 extending in the column direction, and hence the region where the adhesive 24 intimately contacts the transparent substrate 11 is increased, thereby further improving adhesion.

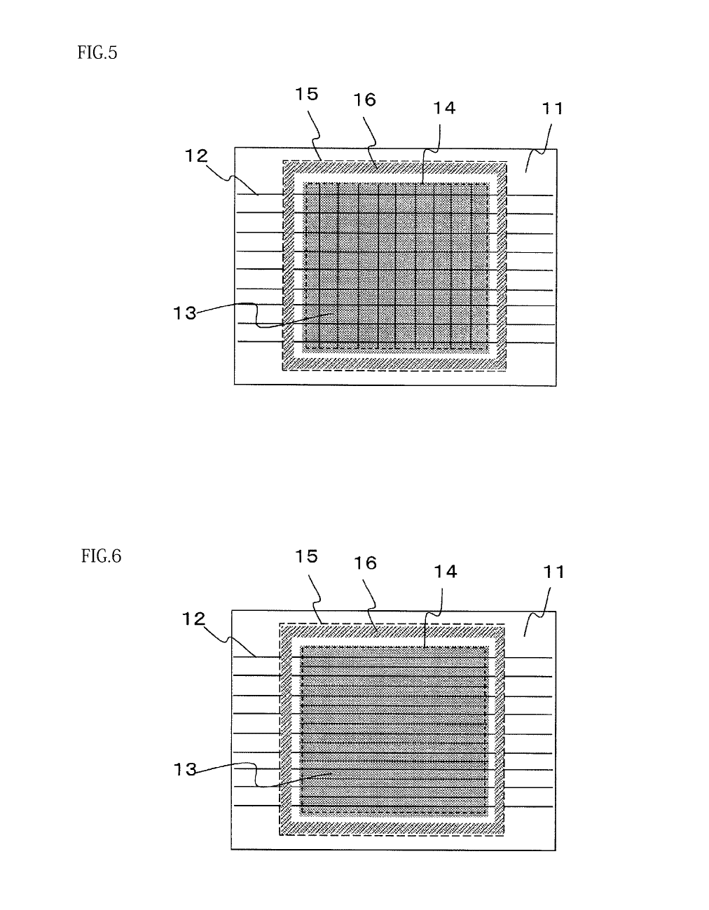

FIG. 3 shows the thin line structure 12 in a grid pattern. Alternatively, however, as shown in FIG. 4, the thin line structure 12 may be extended in one direction (row direction: right-and-left direction as viewed in FIG. 4), forming a stripe pattern continuing to the outside of the sealing substrate-arranging region 15 to serve as an extraction electrode on the outer side of the sealing substrate 23. Then, the transparent conductive layer 13 is formed only inside the sealing substrate-arranging region 15, thereby preparing a transparent electrode. In this case as well, advantageous effects similar to those of the thin line structure 12 in a grid pattern shown in FIG. 3 can be obtained.

### Second Embodiment

A light-emitting device according to a second embodiment will be described.

### Configuration of Transparent Electrode

The light-emitting device according to the second embodiment is basically similar, in configuration and fabrication method, to those of the first embodiment. However, the second embodiment differs from the first embodiment in the configuration in plan view of the thin line structure 12 of the transparent electrode. Accordingly, the following description sets forth the configuration of the transparent electrode referring to FIGS. 5 and 6, omitting description of the rest of the configuration.

In the first embodiment, the configuration in which the thin line structure 12 is uniformly formed has been described. In contrast to this, the second embodiment shows an example in which the pattern of the thin line structure 12 is different between the light-emitting region 14 and the non-light-emitting region.

FIG. 5 is a schematic plan view illustrating the thin line structure 12 and the transparent conductive layer 13, which are formed on the transparent substrate 11. For the sake of clarity, FIG. 5 only shows the sealing substrate-arranging region 15, the adhesive-forming region 16, and the light-emitting region 14, omitting the organic EL layer 21, the cathode layer 22, and the sealing substrate 23.

In the example shown in FIG. 5, the thin line structure 12 is arranged in a grid pattern only in the light-emitting region of the transparent substrate 11. In this case, the transparent electrode is configured such that the shape of the thin line structure 12 is different between the light-emitting region 14 and the non-light-emitting region (outside the adhesive-forming region 16), and that the density of the thin line structure 12 on the transparent substrate 11 is smaller in the non-light-emitting region.

The transparent conductive layer 13 is formed in a manner similar to the first embodiment.

Specifically, let us discuss, in forming the transparent conductive layer 13, the case where, as shown in FIG. 5, the thin line structure 12 is formed in a grid pattern and where the thin line structure 12 is defined, on a direction basis, by a row direction (right-and-left direction as viewed in FIG. 5) and by a column direction (up-and-down direction as viewed in FIG. 5). In this case, in the non-light-emitting region, thin lines are not formed in the column direction but only in the row direction, so that the density of the thin line structure 12 is reduced on the transparent substrate 11 in the non-light-emitting region. In forming the transparent conductive layer 13, only the row-direction thin line structure 12 is formed in the non-light-emitting region. Thus, the density is ensured to be approximately ½, although the density depends on the thin line structure. The density of the thin line structure 12 can be further reduced by reducing the number of thin lines in the row direction in the non-light-emitting region.

FIG. 6 shows an example of a stripe pattern in which the thin line structure 12 extends in one direction (row direction: right-and-left direction as viewed in FIG. 6). In this case, the number of thin lines forming the stripe pattern is reduced in the non-light-emitting region to reduce the density of the thin line structure 12 on the transparent substrate 11 in the non-light-emitting region. In this case, the number of thin lines extending in the row direction of the structure only has to be reduced in the non-light-emitting region. There is a limitation in the reduction, depending on the resistance needed as an extraction electrode. In view of the advantageous effects achieved by the reduction, it is preferable to reduce the number of lines of the thin line structure 12 in the non-light-emitting region to ½ or less, and more preferable ⅓ or less of the light-emitting region.

### Advantageous Effects and Others

The following description sets forth advantageous effects obtained by using the foregoing configurations of the transparent electrodes illustrated in FIGS. 5 and 6.

In the present embodiment, the thin line structure 12 is formed such that the density thereof on the transparent substrate 11 is smaller in the non-light-emitting region. Thus, the configuration of the second embodiment, particularly the thin line structure 12 in a stripe pattern shown in FIG. 6, can reduce the region where the thin line structure 12 is intimately in contact with the adhesive 24, compared to the configuration of the first embodiment. Accordingly, the second embodiment can increase the region where the transparent substrate 11 is intimately in contact with the adhesive 24, thereby further improving adhesion. The second embodiment can reduce the volume (or area) of the thin line structure 12 formed on the transparent substrate 11, regardless of the shape of the thin line structure 12. Since the amount of the material used for the thin line structure 12 can be reduced, the second embodiment is more preferable.

Additionally, as a matter of course, detailed structures and the like can be appropriately modified.

A transparent conductive layer may be formed, for example, by coating or printing using an ink made of a conductive high-molecular-weight material. In this case, after the ink has been injected or transferred onto a substrate, the solvent contained in the ink is evaporated to dry and solidify the ink, thereby forming a coating film serving as the transparent conductive layer. The transparent conductive layer thus formed serves as a transparent electrode surface of the organic EL element. Therefore, the transparent electrode is desired to meet many goals such as being easily formable in a thin film on the transparent substrate where the thin line structure is formed, having injectability as an electrode of the organic EL element, having electrical resistance, and adhering to an adhesive in a sealing structure.

Since the transparent electrode has high flexibility, the organic EL element provided with the transparent electrode can be favorably used for flexible device applications. In such an organic EL element, in a region where an adhesive is formed, the transparent conductive layer needs, on one hand, to intimately contact the transparent substrate while also needing, on the other hand, to intimately contact the adhesive. If the intimate contact is different between both surfaces of the transparent conductive layer, there is a problem of peeling easily occurring at an interface where the contact is weak, leading to impairing reliability. Moreover, the transparent conductive layer is interposed at a boundary of a structure which is hermetically closed by sealing. This raises another problem that the transparent conductive layer needs to have low moisture permeability.

The present invention, in one embodiment, can provide a light-emitting device including a transparent electrode made up of a thin line structure and a transparent conductive layer, the light-emitting device having high light-emission reliability, and a method for fabricating the light-emitting device.

A light-emitting device in an aspect of the present invention is characterized in that the device includes: a transparent substrate; a thin line structure formed by arranging, on the transparent substrate, a plurality of thin lines in a stripe or lattice pattern, the plurality of thin lines being made of an electrically conductive material; a transparent conductive layer formed on the transparent substrate where the thin line structure is formed; a light-emitting functional layer and an electrode laminated in this order on the transparent conductive layer; an adhesive arranged so as to surround, in plan view, a light-emitting region where the light-emitting functional layer and the electrode are formed; and a sealing substrate joined to the transparent substrate via the adhesive, wherein the transparent conductive layer is not interposed between the adhesive and the transparent substrate.

A method for fabricating a light-emitting device in an aspect of the present invention is characterized in that the method includes: forming a thin line structure by arranging, on a transparent substrate, a plurality of thin lines in a stripe or lattice pattern, the plurality of thin lines being made of an electrically conductive material; forming a transparent conductive layer on the transparent substrate where the thin line structure is formed; laminating a light-emitting functional layer and an electrode in this order on the transparent conductive layer; arranging an adhesive so as to surround, in plan view, a light-emitting region where the light-emitting functional layer and the electrode are formed; and joining a sealing substrate to the transparent substrate via the adhesive, wherein the transparent conductive layer is not interposed between the adhesive and the transparent substrate.

According to embodiments of the present invention, adhesion is improved between the adhesive and the transparent substrate where the transparent electrode made up of the thin line structure and the transparent conductive layer is formed. Accordingly, when the sealing substrate is bonded to the structure, a light-emitting device having high light-emitting reliability can be obtained. Consequently, a highly flexible light-emitting device having good long-term reliability can be obtained.

All the contents of Japanese Patent Application No. 2014-006013 (filed Jan. 16, 2014) based on which the present application claims priority are incorporated herein by reference. Description has so far been provided with reference to a limited number of embodiments. However, the scope of rights should not be construed as being limited to the foregoing embodiments. It is self-evident for those skilled in the art to modify the embodiments based on the foregoing disclosure.

### REFERENCE SIGNS LIST

11: Transparent substrate
12: Thin line structure
13: Transparent conductive layer
14: Light-emitting region
15: Sealing substrate-arranging region
16: Adhesive-forming region
21: Organic EL layer
22: Cathode layer
23: Sealing substrate
24: Adhesive.
   Obviously, numerous modifications and variations of the present invention are possible in light of the above teachings. It is therefore to be understood that within the scope of the appended claims, the invention may be practiced otherwise than as specifically described herein.

What is claimed is:

1. A light-emitting device, comprising:
a transparent substrate;
a thin line structure formed on a portion of the transparent substrate and comprising a plurality of thin lines which are formed in a stripe or lattice pattern and comprise an electrically conductive material;
a transparent conductive layer formed on the portion of the transparent substrate where the thin line structure is formed;
a light-emitting functional layer formed on a portion of the transparent conductive layer located in a light-emitting region;
an electrode positioned on the light-emitting functional layer on an opposite side of the transparent conductive layer in the light-emitting region; and
a sealing substrate positioned over the electrode and attached to the transparent substrate via an adhesive,
wherein the adhesive is applied to the transparent substrate such that the transparent conductive layer is not interposed between the adhesive and the transparent substrate, and that the adhesive is formed around the light-emitting region in plan view.

2. The light-emitting device of claim 1, wherein the thin line structure is formed such that thin lines formed in a portion overlapping with the adhesive in plan view extend in one direction intersecting a direction along which the adhesive extends.

3. The light-emitting device of claim 1, wherein, in plan view, the thin line structure is formed in the light-emitting region and extends outside a region surrounded by the adhesive.

4. The light-emitting device of claim 2, wherein, in plan view, the thin line structure is formed in the light-emitting region and extends outside a region surrounded by the adhesive.

5. The light-emitting device of claim 3, wherein, in plan view, the thin line structure located outside the region surrounded by the adhesive includes thin lines formed at a density smaller than in the thin line structure located in the light-emitting region.

6. The light-emitting device of claim 3, wherein the transparent conductive layer is formed on the thin line structure located outside the region surrounded by the adhesive.

7. The light-emitting device of claim 5, wherein the transparent conductive layer is formed on the thin line structure located outside the region surrounded by the adhesive.

8. A method of manufacturing a light-emitting device, comprising:
forming a plurality of thin lines comprising an electrically conductive material in a stripe or lattice pattern on a portion of a transparent substrate such that a thin line structure is formed on the portion of the transparent substrate;
forming a transparent conductive layer on the portion of the transparent substrate where the thin line structure is formed;
forming a light-emitting functional layer on a portion of the transparent conductive layer located in a light-emitting region;
positioning an electrode on the light-emitting functional layer on an opposite side of the transparent conductive layer in the light-emitting region;
applying an adhesive to the transparent substrate; and
attaching a sealing substrate to the transparent substrate via the adhesive such that the sealing substrate is positioned over the electrode,
wherein the adhesive is applied to the transparent substrate such that the transparent conductive layer is not interposed between the adhesive and the transparent substrate, and that the adhesive is formed around the light-emitting region in plan view.

9. The method of claim 8, wherein the forming of the plurality of thin lines includes forming thin lines in a portion overlapping with the adhesive in plan view which extend in one direction intersecting a direction along which the adhesive extends.

10. The method of claim 8, wherein, in plan view, the thin line structure is formed in the light-emitting region and extends outside a region surrounded by the adhesive.

11. The method of claim 9, wherein, in plan view, the thin line structure is formed in the light-emitting region and extends outside a region surrounded by the adhesive.

12. The method of claim 10, wherein the forming of the plurality of thin lines includes forming thin lines in the thin line structure located outside the region surrounded by the adhesive at a density smaller than in the thin line structure located in the light-emitting region.

13. The method of claim 10, wherein the transparent conductive layer is formed on the thin line structure located outside the region surrounded by the adhesive.

14. The method of claim 12, wherein the transparent conductive layer is formed on the thin line structure located outside the region surrounded by the adhesive.

15. The method of claim 12, wherein the forming of the transparent conductive layer includes forming a portion of the transparent conductive layer outside of the region surrounded by the adhesive in plan view, simultaneously with forming a portion of the transparent conductive layer in the light-emitting region.
